(19) United States
(12) Patent Application Publication
(10) Pub. No.: US 2007/0187806 A1
(43) Pub. Date: Aug. 16, 2007

(54) Semiconductor chip package mounting structure implementing flexible circuit board

(75) Inventors: Min-Woo Kim, Seoul (KR); Sung-Wook Hwang, Seongnam-si (KR); Gwang-Man Lim, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/505,323

(22) Filed: Aug. 17, 2006

(30) Foreign Application Priority Data
Feb. 13, 2006 (KR) 2006-013829

(51) Int. Cl. H01L 23/495

(52) U.S. Cl. 257/668; 257/E23.065

(57) ABSTRACT

A semiconductor chip package mounting structure may mount a semiconductor chip package on a module board by implementing a flexible circuit board. The semiconductor chip package may be electrically connected to a first surface of the flexible circuit board and the module board may be electrically connected to a second surface of the flexible circuit board.

### PRIORITY STATEMENT

This U.S. non-provisional application claims benefit of priority under 35 U.S.C. §119 from Korean Patent Application No. 2006-13829, filed on Feb. 13, 2006 in the Korean Intellectual Property Office (KIPO), the entire contents of which are incorporated herein by reference.

### BACKGROUND

1. Field of the Invention

Example embodiments of the present invention relate to a semiconductor chip package mounting structure, and more particularly to a semiconductor chip package mounting structure implementing a flexible circuit board.

2. Description of the Related Art

Portable electronic devices, for example digital cameras and mobile phones, may be miniaturized and/or have multifunction capabilities. Such devices may implement System in Package (SiP) modules. An SiP module may include a module board, which may accommodate electronic components including semiconductor chip packages. However, there may be limitations in reducing the size of SiP modules.

FIG. 1 is a plan view of a conventional semiconductor chip package mounting structure. FIG. 2 is a side view of the semiconductor chip package mounting structure in FIG. 1.

Referring to FIGS. 1 and 2, an electronic module 510, for use in a mobile phone (for example), may include a module board 520, a plurality of semiconductor chip packages 531, 532, 533 and a passive device 539 provided on the module board 520. The semiconductor chip packages 531, 532, 533 may be electrically connected to the module board 520.

FIG. 3 is a plan view of a structural variation of an electronic module 510.

Referring to FIG. 3, the electronic module 510 may have function blocks, for example a multimedia block 561 and/or a communication block 562. The function blocks may be implemented to provide multifunction features. For example, the multimedia block 561 may include an MP3 function and/or a camera function, and the communication block 562 may include a Wireless LAN (WLAN) function, a Wireless Broadband Internet (WiBro) function and/or a GPS function. The implementation of multifunction may increase the size of the module board 520.

As the size of a semiconductor chip package decreases, a solder joint area between a semiconductor chip package and a module board may decrease. As a result, package mounting reliability may be reduced in electrical and/or mechanical aspects.

### SUMMARY

Example embodiments of the present invention provide a semiconductor chip package mounting structure that may reduce the size of an electronic module, for example.

Example embodiments of the present invention may provide a semiconductor chip package mounting structure that may provide reliable mounting of a semiconductor chip package, for example.

According to an example embodiment of the present invention, a semiconductor chip package mounting structure may include a module board having a plurality of connection pads. A semiconductor chip package may be mounted on the module board and may have external connection terminals. A flexible circuit board may have metal wirings. The flexible circuit board may have a first surface electrically connected to the semiconductor chip package and a second surface electrically connected to the module board. The semiconductor chip package may be arranged at a desired position by implementing the flexible circuit board.

According to an example embodiment of the present invention, the flexible circuit board may be bump-bonded to the module board. The flexible circuit board may have an insulating layer in which the metal wirings are formed.

According to an example embodiment of the present invention, the flexible circuit board may have a plurality of land pads. The land pads may include land pads of a first land pad group connected to the external connection terminals of the semiconductor chip package, and land pads of a second land pad group bump-bonded to the connection pads of the module board. The metal wirings may connect the land pads of the first land pad group to the land pads of the second land pad group.

According to an example embodiment of the present invention, the land pads of the first land pad group may be exposed from the insulating layer in a first direction and the land pads of the second land pad group may be exposed from the insulating layer in a second direction.

According to an example embodiment of the present invention, the external connection terminals may include conductive bumps provided on one surface of the semiconductor chip package in a matrix arrangement. The flexible circuit board may have land pads of a first land pad group connected to the conductive bumps of the semiconductor chip package and land pads of a second land pad group bump-bonded to the connection pads of the module board. The area containing the land pads of the second land pad group may be substantially equal in size to the area containing the conductive bumps.

An example embodiment of the present invention provides a semiconductor chip mounting structure. The semiconductor chip package mounting structure may include a plurality of semiconductor chip packages and a plurality of flexible circuit boards.

According to an example embodiment of the present invention, each of the flexible circuit boards may have land pads of a merge land pad group and land pads of an independent land pad group. The land pads of the merge land pad groups of the flexible circuit boards may be commonly connected to the semiconductor chip packages, and the land pads of the independent land pad groups of the flexible circuit boards may be connected to the corresponding semiconductor chip packages. When the flexible circuit boards are stacked, the land pads of the merge land pad groups may be bump-bonded to each other between different flexible circuit boards, whereas the land pads of the independent land pad groups may be electrically disconnected to each other between different flexible circuit boards.

According to an example embodiment of the present invention, at least one flexible circuit board may have land pads of an isolated land pad group. The land pads of the isolated land pad group may be electrically isolated from the land pads of the merge land pad group and the land pads of the independent land pad group. The land pads of the isolated land pad group may vertically connect the land pads of the independent land pad groups of the flexible circuit boards. The land pads of the independent land pad groups may be arranged not corresponding to each other between the flexible circuit boards.

According to example embodiments of the present invention, the semiconductor chip package may include a ball grid array semiconductor chip package, a land grid array semiconductor chip package and/or a leadframe based semiconductor chip package.

### BRIEF DESCRIPTION OF THE DRAWINGS

Example embodiments of the present invention will be readily understood with reference to the following detailed description thereof provided in conjunction with the accompanying drawings, wherein like reference numerals designate like structural elements.

FIG. 1 is a plan view of a conventional semiconductor chip package mounting structure.

FIG. 2 is a side view of the semiconductor chip package mounting structure in FIG. 1.

FIG. 3 is a plan view of a structural variation of a module board in FIG. 1.

FIG. 4 is a plan view of an electronic module that may implement a semiconductor chip package mounting structure in accordance with an example embodiment of the present invention.

FIG. 5 is a side view of the electronic module in FIG. 4.

FIG. 6 is a bottom view of the semiconductor chip package mounting structure in FIG. 4.

FIG. 7 is a cross-sectional view of a semiconductor chip package mounting structure in accordance with an example embodiment of the present invention.

FIG. 8 is a cross-sectional view of a semiconductor chip package mounting structure in accordance with another example embodiment of the present invention.

FIG. 9 is a side view of an electronic module implementing the semiconductor chip package mounting structure in FIG. 8.

FIG. 10 is a plan view of a portion of the module board in FIG. 9.

FIGS. 11 to 13 are schematic views of electrical connections between flexible circuit boards and semiconductor chip packages in FIG. 9.

FIG. 14 is a cross-sectional view of a semiconductor chip package mounting structure in accordance with another example embodiment of the present invention.

FIG. 15 is a cross-sectional view of a semiconductor chip package mounting structure in accordance with another example embodiment of the present invention.

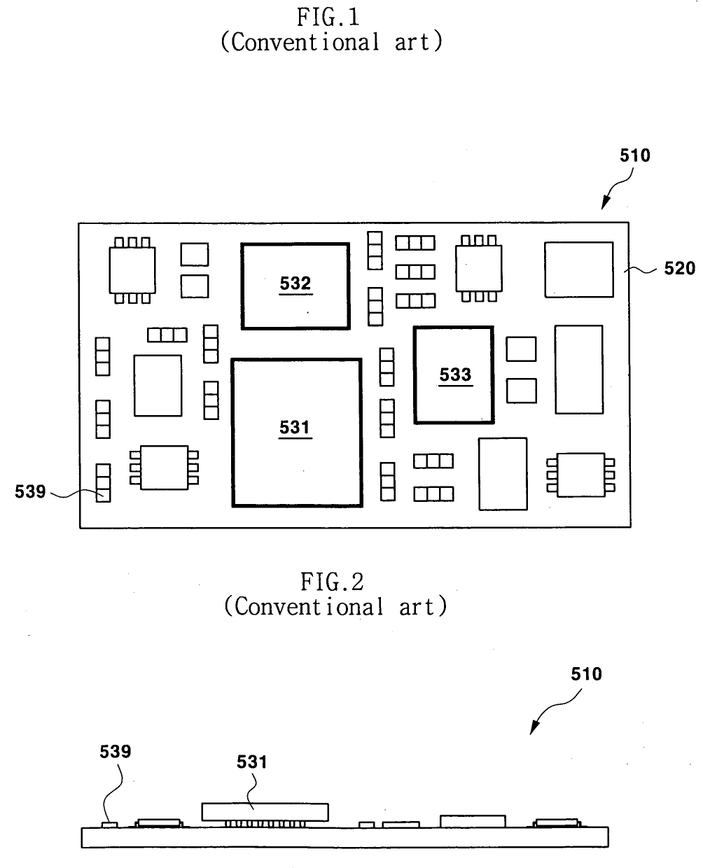

The drawings are for illustrative purposes only and are not drawn to scale. The spatial relationships and/or relative sizing of the elements illustrated in the various embodiments may have been reduced, expanded or rearranged to improve the clarity of the figures with respect to the corresponding description. The figures, therefore, should not be interpreted as accurately reflecting the relative sizing and/or positioning of the corresponding structural elements that could be encompassed by an actual device manufactured according to the example embodiments of the invention.

### DESCRIPTION OF EXAMPLE NON-LIMITING EMBODIMENTS

Example, non-limiting embodiments of the present invention will now be described more fully hereinafter with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

The figures are intended to illustrate the general characteristics of methods and/or devices of example embodiments of this invention, for the purpose of the description of such example embodiments herein. The drawings are not, however, to scale and may not precisely reflect the characteristics of any given embodiment, and should not be interpreted as defining or limiting the range of values or properties of example embodiments within the scope of this invention. Rather, for simplicity and clarity of illustration, the dimensions of some of the elements may be exaggerated relative to other elements.

Well-known structures and processes are not described or illustrated in detail to avoid obscuring the present invention.

An element is considered as being mounted (or provided) “on” another element when mounted or provided) either directly on the referenced element or mounted (or provided) on other elements overlaying the referenced element. Throughout this disclosure, spatial terms such as “upper,” “lower,” “above” and “below” (for example) are used for convenience in describing various elements or portions or regions of the elements as shown in the figures. These terms do not, however, require that the structure be maintained in any particular orientation.

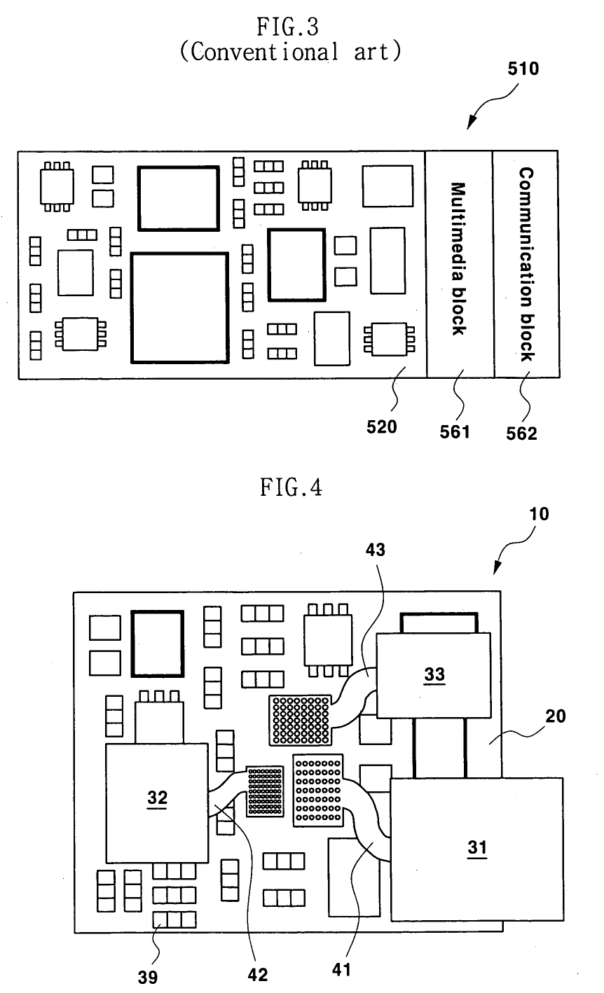

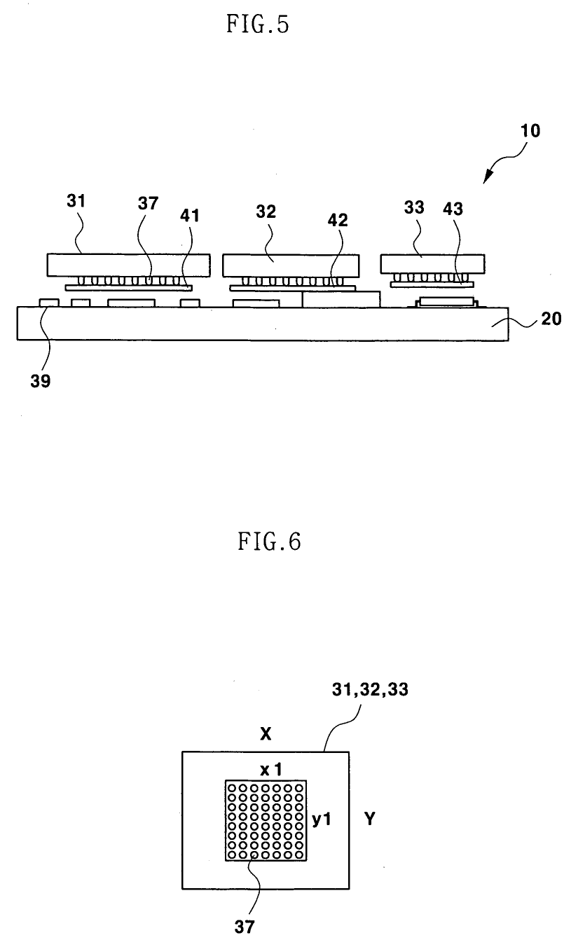

FIG. 4 is a plan view of an electronic module 10 that may implement a semiconductor chip package mounting structure in accordance with an example embodiment of the present invention. FIG. 5 is a side view of the electronic module 10 in FIG. 4. FIG. 6 is a bottom view of the semiconductor chip package mounting structure in FIG. 4.

Referring to FIGS. 4 and 5, the electronic module 10, for a mobile phone (for example), may include a module board 20. Semiconductor chip packages 31, 32 and 33 and a passive device 39 may be mounted on the module board 20. Flexible circuit boards 41, 42 and 43 may connect the semiconductor chip packages 31, 32 and 33, respectively, to the module board 20.

The semiconductor chip packages 31, 32 and 33 may include a first semiconductor chip package 31 (which may serve as an operating drive, for example), a second semiconductor chip package 32 (which may serve as a working memory, for example) and a third semiconductor chip package 33 (which may serve as a storage memory, for example). By way of example only, the semiconductor chip packages 31, 32 and 33 may be ball grid array semiconductor chip packages that may have external connection terminals 37 provided on one surface thereof in a matrix arrangement. As shown in FIG. 6, the area (x1*y1) containing the external connection terminals 37 may be smaller than the area (X*Y) of each of the semiconductor chip packages 31, 32 and 33.

Each of the flexible circuit boards 41, 42 and 43 may have a first surface and a second surface. The first surface may be connected to the semiconductor chip packages 31, 32 and 33 and the second surface may be connected to the module board 20. The use of the flexible circuit boards 41, 42 and 43 may allow for indirect attachment of the semiconductor chip packages 31, 32 and 33 to the module board 20. By virtue of the flexible circuit boards 41, 42 and 43, the semiconductor chip packages 31, 32 and 33 may be arranged at a desired position beyond the limited area of the module board 20.

The connection area between each of the flexible circuit boards 41, 42 and 43 and the module board 20 may not be larger than the area (x1*y1) containing the external connection terminals 37. For example, the connection area between the flexible circuit board 41 and the module board 20 may be substantially equal to the area (x1*y1) containing the external connection terminals 37. In this way, the module board 20 may have a reduced mounting area for mounting the semiconductor chip package 31.

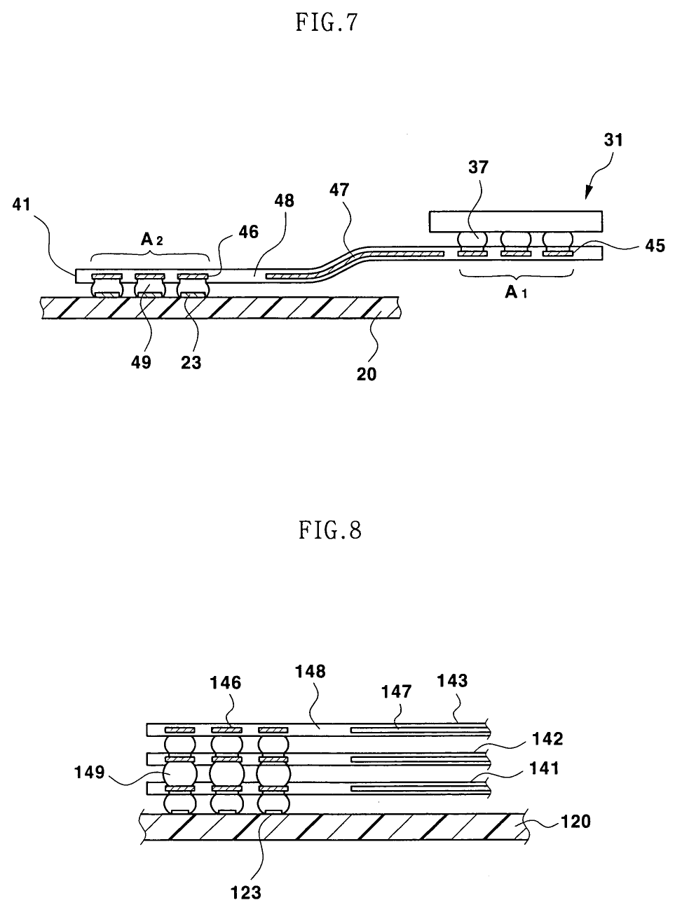

FIG. 7 is a cross-sectional view of a semiconductor chip package mounting structure in accordance with an example embodiment of the present invention. This example embodiment shows the semiconductor chip package 31 and the flexible circuit board 41.

Referring to FIG. 7, a module board 20 may have connection pads 23. The connection pads 23 may be arranged corresponding to external connection terminals 37 of the semiconductor chip package 31. The module board 20 may include a printed circuit board, for example.

The semiconductor chip package 31, which may be a ball grid array semiconductor chip package (for example), may have the external connection terminals 37 provided on one surface thereof. By way of example only, the external connection terminals 37 may include solder bumps and/or Au bumps.

The flexible circuit board 41 may have an insulating layer 48, and land pads 45 and 46 and metal wirings 47 formed in the insulating layer 48. A portion of the land pads 45 and 46 may be exposed from the insulating layer 48. By way of example only, the flexible circuit board 41 may include a board fabricated from a polyimide film and metal wirings, or a substrate fabricated from flexible materials.

The land pads 45 and 46 may include land pads 45 of a first land pad group (A1) and land pads 46 of a second land pad group (A2). The land pads 45 of the first land pad group (A1) may be arranged at one side of the flexible circuit board 41 to provide electrical connection to the semiconductor chip package 31, and the land pads 46 of the second land pad group (A2) may be arranged at the other side of the flexible circuit board 41 to provide electrical connection to the module board 20. The land pads 45 of the first land pad group (A1) may be connected to the land pads 46 of the second land pad group (A2) by the metal wirings 47.

The land pads 45 of the first land pad group (A1) may be exposed from the insulating layer 48 in a first direction and the land pads 46 of the second land pad group (A2) may be exposed from the insulating layer 48 in a second direction. The land pads 46 of the second land pad group (A2) may be connected to the connection pads 23 of the module board 20 by conductive bumps 49, such as solder balls (for example). The land pads 45 of the first land pad group (A1) may be bump-bonded to the external connection terminals 37 of the semiconductor chip package 31. In this way, the semiconductor chip package 31 may be electrically connected to the module board 20. In this example embodiment, each of the flexible circuit boards 41, 42 and 43 may be superposed above different regions of the module board 20, as shown in FIG. 4.

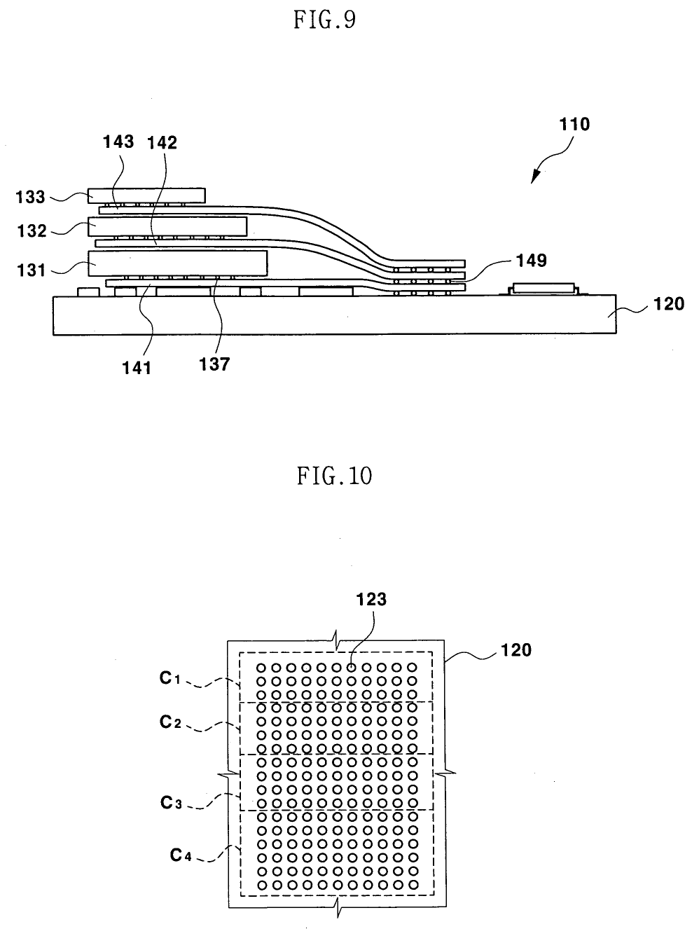

FIG. 8 is a cross-sectional view of a semiconductor chip package mounting structure in accordance with another example embodiment of the present invention. FIG. 9 is a side view of an electronic module 110 implementing the semiconductor chip package mounting structure in FIG. 8.

Referring to FIGS. 8 and 9, semiconductor chip packages 131, 132 and 133 may be attached to the upper side of flexible circuit boards 141, 142 and 143, respectively. The flexible circuit boards 141, 142 and 143 may be stacked on the module board 120 using conductive bumps 149. The conductive bumps 149 may be provided on the lower side of the flexible circuit boards 141, 142 and 143. The semiconductor chip package mounting structure of this example embodiment may implement electrical interconnections between the flexible circuit boards 141, 142 and 143. In this way, the module board 120 may have a reduced mounting area for mounting the flexible circuit boards 141, 142 and 143. The flexible circuit boards 141, 142 and 143 may serve as heat radiation routes to improve the thermal characteristic of the electronic module 110. The semiconductor chip packages 131, 132 and 133 may be attached to the flexible circuit boards 141, 142 and 143, which may reduce vulnerability to mechanical stresses (for example).

FIG. 10 is a plan view of a portion of the module board 120 in FIG. 9.

Referring to FIG. 10, the module board 120 may have connection pads 123 provided on one surface thereof in a matrix arrangement. The connection pads 123 may include connection pads of a merge connection pad group C1 and connection pads of independent connection pad groups C2, C3 and C4. The connection pads of the merge connection pad group C1 may be commonly connected to the semiconductor chip packages 131, 132 and 133. The connection pads of the independent connection pad groups C2, C3 and C4 may be connected to the corresponding semiconductor chip packages 133, 132 and 131, respectively.

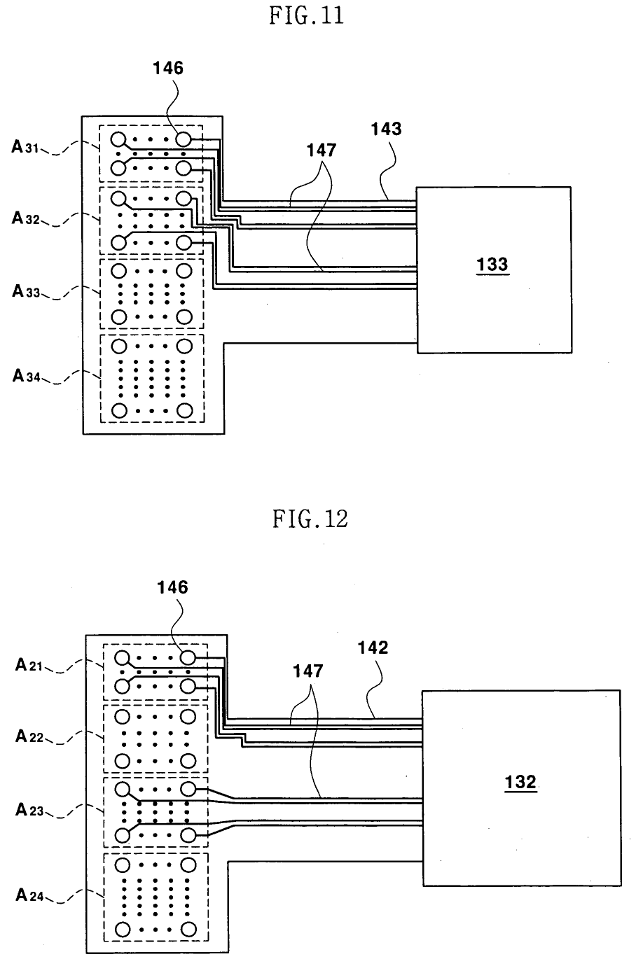

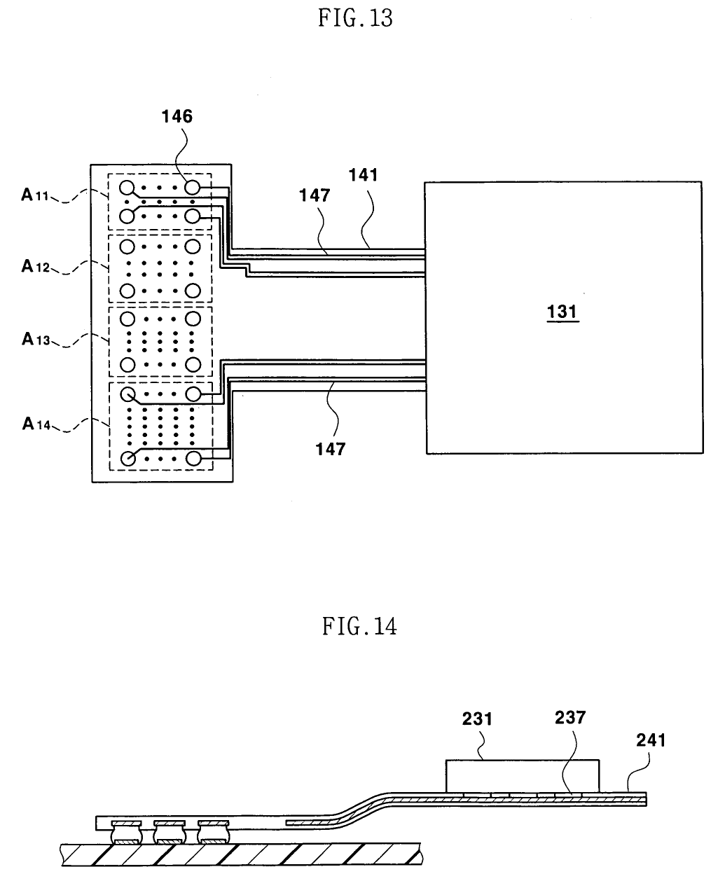

FIGS. 11 to 13 are schematic views of electrical connections between, respectively, the flexible circuit boards 143, 142 and 141 and the semiconductor chip packages 133, 132 and 131 in FIG. 9.

Referring to FIGS. 11 to 13, the flexible circuit boards 141, 142 and 143 may have land pads 146 including land pads of merge land pad groups A11, A21 and A31 and land pads of independent land pad groups A14, A23, and A32, respectively. The land pads of the merge land pad groups A11, A21 and A31 may be respectively arranged on the flexible circuit boards 141, 142 and 143 corresponding to each other in a matrix arrangement. The land pads of the independent land pad groups A14, A23 and A32 may be connected to the corresponding semiconductor chip packages 131, 132 and 133, respectively. The flexible circuit boards 141, 142 and 143 may have land pads of isolated land pad groups A12 and A13, A22 and A24, and A33 and A34, respectively. The land pads of the isolated land pad groups A33 and A34, A22 and A24, and A12 and A13 may be electrically isolated from the land pads of the merge land pad groups A31, A21 and A11 and the land pads of the independent land pad groups A32, A23 and A14, respectively. The land pads of the isolated land pad groups A33 and A34, A22 and A24, and A12 and A13 may connect the land pads of independent land pad groups A32, A23 and A14 to the module board 120. For example, the independent land pad group A32 of the flexible circuit board 143 may be electrically connected to independent connection pad group C2 of the module board 120 via the isolated land pad group A22 of the flexible circuit board 142, the isolated land pad group A12 of the flexible circuit board 141 and the conductive bumps 149. The flexible circuit boards 141, 142 and 143 may have metal wirings 147.

The semiconductor chip package mounting structure of this example embodiment may stack a plurality of flexible circuit boards so that the flexible circuit boards may be superposed above common regions of the module board. Also, land pads of the merge land pad groups may be bump-bonded and electrically connected to each other between the flexible circuit boards, and land pads of the independent land pad groups (which may be connected to the corresponding flexible circuit boards) may be electrically connected to the module board through land pads of an isolated land pad group of one or more lower flexible circuit boards. In this way, semiconductor chip packages may be interconnected within a substrate, thus reducing the size of the module board.

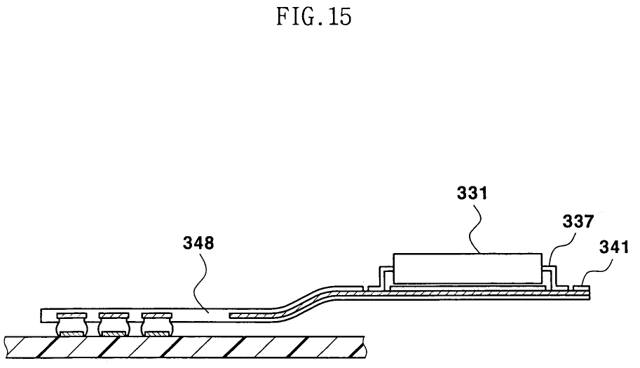

FIG. 14 is a cross-sectional view of a semiconductor chip package mounting structure in accordance with another example embodiment of the present invention. FIG. 15 is a cross-sectional view of a semiconductor chip package mounting structure in accordance with another example embodiment of the present invention.

Referring to FIG. 14, a semiconductor chip package 231 having chip land pads 237, e.g., a land grid array type semiconductor chip package, may be attached to a flexible circuit board 241.

Referring to FIG. 15, a semiconductor chip package 331 having outer leads 337, e.g., a leadframe based semiconductor chip package, may be attached to a flexible circuit board 341. The flexible circuit board 341 may have an insulating layer 348 formed in conformity to the shape of the outer leads 337.

In accordance with example embodiments of the present invention, a semiconductor chip package mounting structure may provide an electrical connection between a semiconductor chip package and a module board by implementing a flexible circuit board. The flexible circuit board may allow for a reduced mounting area of the module board for mounting the semiconductor chip package and free arrangement of the semiconductor chip package, for example beyond the limited area of the module board.

The semiconductor chip package mounting structure may connect a plurality of semiconductor chip packages to a module board. Accordingly, the size of the module board may be reduced.

The semiconductor chip package mounting structure may improve (for example) reliability against heat and/or external shocks at joints between the semiconductor chip package and the module board.

Although example, non-limiting embodiments of the present invention have been described in detail hereinabove, it should be understood that many variations and/or modifications of the basic inventive concepts taught herein, which may appear to those skilled in the art, will still fall within the spirit and scope of the invention as defined by the appended claims.

What is claimed is:

1. A semiconductor chip package mounting structure comprising:
a module board having connection pads;
at least one semiconductor chip package mounted on the module board, the at least one semiconductor chip package having external connection terminals; and
at least one flexible circuit board having metal wirings, the at least one flexible circuit board having a first surface and a second surface opposite to the first surface,
wherein the at least one semiconductor chip package is attached to and electrically connected to the first surface of the at least one flexible circuit board and the module board is attached to and electrically connected to the second surface of the at least one flexible circuit board.

2. The structure of claim 1, wherein the at least on flexible circuit board is bump-bonded to the module board.

3. The structure of claim 1, wherein the at least one flexible circuit board has an insulating layer in which the metal wirings are formed.

4. The structure of claim 1, wherein the at least one flexible circuit board has a plurality of land pads, the land pads including land pads of a first land pad group connected to the external connection terminals of the at least one semiconductor chip package and land pads of a second land pad group bump-bonded to the connection pads of the module board, and the metal wirings connect the land pads of the first land pad group to the land pads of the second land pad group.

5. The structure of claim 4, wherein the land pads of the first land pad group are exposed on the first surface of the at least one flexible circuit board and the land pads of the second land pad group are exposed on the second surface of the at least one flexible circuit board.

6. The structure of claim 1, wherein the external connection terminals include conductive bumps provided on one surface of the at least one semiconductor chip package in a matrix arrangement.

7. The structure of claim 6, wherein the at least one flexible circuit board has land pads of a first land pad group connected to the conductive bumps of the at least one semiconductor chip package and land pads of a second land pad group bump-bonded to the connection pads of the module board, and the area containing the land pads of the second land pad group is substantially equal in size to the area containing the conductive bumps.

8. The structure of claim 1, comprising a plurality of the semiconductor chip packages and a plurality of the flexible circuit boards.

9. The structure of claim 8, wherein each of the plurality of flexible circuit boards has land pads of a merge land pad group commonly electrically connected to the plurality of semiconductor chip packages and land pads of an independent land pad group connected to a corresponding semiconductor chip package.

10. The structure of claim 9, wherein the plurality of flexible circuit boards is stacked such that the land pads of the merge land pad groups are bump-bonded to each other between the plurality of flexible circuit boards and the land pads of the independent land pad groups are electrically disconnected from each other between the plurality of flexible circuit boards.

11. The structure of claim 10, wherein at least one of the plurality of flexible circuit boards has land pads of an isolated land pad group, the land pads of the isolated land pad group being electrically isolated from the land pads of the merge land pad group and the land pads of the independent land pad group and being configured to connect the land pads of the independent land pad groups of adjacent ones of the plurality of flexible circuit boards to the module board.

12. The structure of claim 10, wherein the land pads of the independent land pad groups are arranged at different positions of the plurality of flexible circuit boards.

13. The structure of claim 11, wherein each of the plurality of flexible circuit boards has land pads of an isolated land pad group.

14. The structure of claim 1, wherein the semiconductor chip package includes a ball grid array semiconductor chip package.

15. The structure of claim 1, wherein the semiconductor chip package includes a land grid array semiconductor chip package.

16. The structure of claim 1, wherein the semiconductor chip package includes a leadframe based semiconductor chip package.
